(19) United States
(12) Patent Application Publication
(10) Pub. No.: US 2024/0055343 A1
(43) Pub. Date: Feb. 15, 2024

(54) SEMICONDUCTOR PACKAGE STRUCTURE

(71) Applicant: AP MEMORY TECHNOLOGY CORPORATION, HSINCHU COUNTY (TW)

(72) Inventors: KEE-WEI CHUNG, HSINCHU COUNTY (TW); RU-YI CAI, HSINCHU COUNTY (TW)

(21) Appl. No.: 18/363,645

(22) Filed: Aug. 1, 2023

Related U.S. Application Data
(60) Provisional application No. 63/371,258, filed on Aug. 12, 2022.

(51) Int. Cl. H01L 23/498; H01L 23/00; H01L 23/15; H01L 25/065; H01L 23/31

(52) U.S. Cl. CPC H01L 23/49838; H01L 24/16; H01L 24/32; H01L 23/15; H01L 25/0652; H01L 23/3107; H10B 80/00

(57) ABSTRACT

A semiconductor package structure is provided. The semiconductor package structure includes a first redistribution structure, a SoC structure, a memory structure, a first electronic component, and a first encapsulation layer. The first redistribution structure has a first side and a second side opposite to the first side. The SoC structure is on the first side of the first redistribution structure. The memory structure is adjacent to the SoC structure and on the first side of the first redistribution structure. The first electronic component is on the second side of the first redistribution structure and electrically connected to at least one of the SoC structure or the memory structure. The first encapsulation layer encapsulates the first electronic component. The first electronic component includes a semiconductor capacitor structure or a voltage converter.

### PRIORITY CLAIM AND CROSS-REFERENCE

This application claims the benefit of prior-filed U.S. provisional application No. 63/371,258, filed on Aug. 12, 2022, and incorporates its entirety herein.

### FIELD

The present disclosure relates to a semiconductor package structure, particularly, the semiconductor package structure includes at least an electronic component packaged with a SoC structure and a memory structure. The SoC structure includes System on a Chip or System-of-Chip. The System-of-Chip featured stack chiplets or 3-Dimensional (3D) chiplets. By utilizing the selected packaged electronic components, the overall packaging structure can provide high-performance capabilities that correspond to the selected electronic components.

### BACKGROUND

Semiconductor packaging structure refers to the process of enclosing a semiconductor device in a protective casing to protect it from external damage and to facilitate its integration into electronic systems. The packaging structure for DRAM (Dynamic Random Access Memory) typically includes a silicon die, which contains the memory cells, mounted on a lead frame or substrate. The die is then encapsulated in a plastic or ceramic package, which provides protection from moisture, dust, and other environmental factors. The package also includes pins or pads that allow for electrical connections to be made between the DRAM and other components in the electronic system.

### BRIEF DESCRIPTION OF THE DRAWINGS

Aspects of the present disclosure are best understood from the following detailed description when read with the accompanying figures. It is noted that, in accordance with the standard practice in the industry, various structures are not drawn to scale. In fact, the dimensions of the various structures may be arbitrarily increased or reduced for clarity of discussion.

FIG. 1 illustrates a cross-sectional view of a semiconductor package structure according to some embodiments of the present disclosure.

FIG. 2 illustrates a cross-sectional view of a semiconductor package structure according to some embodiments of the present disclosure.

FIGS. 3A to 3G illustrate cross-sectional views of forming a semiconductor package structure according to some embodiments of the present disclosure.

FIG. 4A illustrates cross-sectional views of electronic components according to some embodiments of the present disclosure.

FIG. 4B illustrates cross-sectional views of electronic components according to some embodiments of the present disclosure.

FIG. 4C illustrates cross-sectional views of electronic components according to some embodiments of the present disclosure.

FIG. 4D illustrates cross-sectional views of electronic components according to some embodiments of the present disclosure.

FIG. 4E illustrates cross-sectional views of electronic components according to some embodiments of the present disclosure.

FIG. 5 illustrates a cross-sectional view of a semiconductor package structure according to some embodiments of the present disclosure.

FIGS. 6A to 6F illustrate cross-sectional views of forming a semiconductor package structure according to some embodiments of the present disclosure.

FIG. 7 illustrates a cross-sectional view of a semiconductor package structure according to some embodiments of the present disclosure.

FIGS. 8A to 8D illustrate cross-sectional views of forming a semiconductor package structure according to some embodiments of the present disclosure.

FIG. 9 illustrates a cross-sectional view of a semiconductor package structure according to some embodiments of the present disclosure.

FIGS. 10A to 10E illustrate cross-sectional views of forming a semiconductor package structure according to some embodiments of the present disclosure.

FIG. 11 illustrates a cross-sectional view of a semiconductor package structure according to some embodiments of the present disclosure.

FIGS. 12A to 12G illustrate cross-sectional views of forming a semiconductor package structure according to some embodiments of the present disclosure.

FIG. 13 illustrates a cross-sectional view of a semiconductor package structure according to some embodiments of the present disclosure.

FIGS. 14A to 14G illustrate cross-sectional views of forming a semiconductor package structure according to some embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as “first”, “second” and “third” describe various elements, components, regions, layers and/or sections, these elements, components, regions, layers and/or sections should not be limited by these terms. These terms may be only used to distinguish one element, component, region, layer, or section from another. The terms such as “first”, “second”, and “third” when used herein do not imply a sequence or order unless clearly indicated by the context.

SoC is an integrated circuit that integrates most or all components of a computer or other electronic system. Higher-performance SoCs are often paired with dedicated and physically separate memory and secondary storage chips. In some examples, these memory and secondary storage chips may be layered on top of the SoC in what is known as a package on package (PoP) configuration, or be placed close to the SoC. In other examples, some powerful SoC can include chiplet-based architectures. In such examples, the complex functions of the chip are decomposed into multiple small modules (i.e., chiplets), while each of them can perform a single specific function very effectively.

Other than the SoC and the memory, in some embodiments of the present disclosure, more components can be assembled with the SoC and the memory for expanding the function of the packaged structure, or enhancing the performance of the packaged structure. In fact, the fundamental principles underlying the functionality of electronic equipment are rooted in the amalgamation and interplay of various electronic components. Nonetheless, the integration of multiple electronic components into microstructures through packaging technology, while taking into account process compatibility, cost-effectiveness, and space utilization, is a crucial area of focus for further development.

In some embodiments of the present disclosure, there are several suitable components can be selected to be assembled with SoC and memory for providing a functional, high-speed performance, and reliable chip structure. In some embodiments, at least one of a component selected from the group consisting of silicon bridge die, semiconductor capacitor die, and voltage converter e.g., fully integrated voltage regulator (FIVR) die may be used to package with the SoC and memory, while which component(s) is selected and thus being electrically communicate and work with the SoC and memory, is depending on the purpose of the final product.

The silicon bridge is a densely packed multi-chip packaging architecture that allows for high die-to-die interconnect density and corresponding applications. In some embodiments, a silicon bridge die that is packaged in the semiconductor structure with a SoC and a memory can be used to provide a metal connection with finer line width/space between the SoC and the memory.

The semiconductor capacitor is manufactured over a semiconductor substrate such as silicon or germanium using semiconductor process technology. In some embodiments, the semiconductor capacitor can be a single metal-insulator-metal (MIM) or multiple MIM structure electrostatic capacitor built using semiconductor technologies. In some embodiments, a semiconductor capacitor die packaged in the semiconductor structure can be used to replace multi-layer ceramic capacitors (MLCCs) which are typically made in a rectangular block for surface mounting. In some embodiments, power integrity can be improved due to the close distance between the semiconductor devices and the semiconductor capacitor. Generally, by using the semiconductor capacitor, overall computational efficiency can be upgraded, and capacitance density can be increased as well. In addition, there are several considerable features of semiconductor capacitors, including thin dimensions, low equivalent series inductance (ESL) and equivalent series resistance (ESR), high capacitance, and low dependence on temperature and voltage.

The voltage converter is an electric power converter that can change the voltage of an electrical power source. In certain applications, the voltage converter can have enhanced functionality, such as the ability to produce a fixed voltage regardless of the input voltage, like an FIVR. Typically, a fixed ratio voltage converter (e.g., 3:1) is sufficient. The regulation function can be achieved with the input voltage, while for some capacitor-based voltage converters, the advantage is most noticeable when used in this manner.

FIVR can be simply referred to as an integrated voltage regulator (IVR) in certain scenarios. It can enhance supply integrity and enable flexible voltage scaling by moving power conversion closer to the point-of-load. In some examples, the FIVR die includes active device such as a power management integrated circuit (PMIC) and passive components such as semiconductor capacitors to enhance power integrity and reduce overall cost of the semiconductor structure. By using the FIVR die, the PCB footprint can be reduced for small systems, and the low inductance loop of FIVR is beneficial for reducing voltage drop. Furthermore, the size of the related semiconductor structure can be reduced by replacing the power gating device on SoC with FIVR, and the cost thereof is also decreased since the discrete inductors and capacitors are eliminated, and the supply current to package/socket can be reduced.

In order to integrate these functional components into a single semiconductor package structure, there are several aspects such as performance effectiveness, process rationality, suitability, overall cost, etc., should be taken into account. Particularly, the relative positions of the SoC, the memory, and the selected components including silicon bridge die, semiconductor capacitor (e.g., silicon capacitor die), and voltage converter (e.g., FIVR die), should be considered properly.

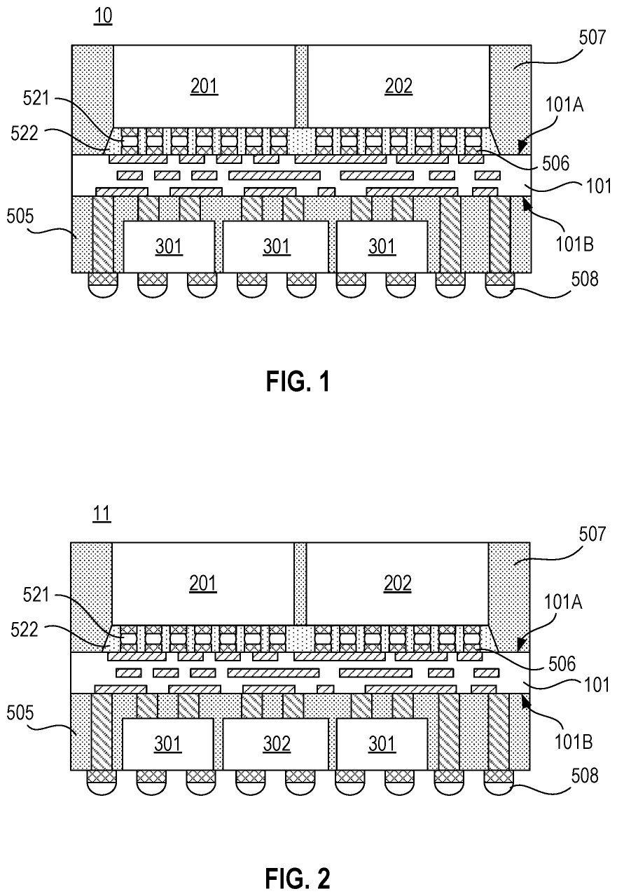

Referring to FIG. 1, in some embodiment, the semiconductor package structure 10 includes a first redistribution structure 101, a SoC structure 201, a memory structure 202, and one or more first electronic components 301. The first redistribution structure 101 includes a first side 101A and a second side 101B opposite to the first side 101A. In some embodiments, the first redistribution structure 101 is used to provide electrical communication between the components disposed on two sides thereof. As shown in FIG. 1 both the SoC structure 201 and the memory structure 202 are disposed on the first side 101A of the first redistribution structure 101, while the first electronic components 301 are disposed on the second side 101B of the first redistribution structure 101. Specifically, the SoC structure 201 and the memory structure 202 may be bonded on the first side 101A of the first redistribution structure 101 through bumping structures, and the first electronic components 301 are connected to the second side 101B of the first redistribution structure 101 with a conductive material.

In some embodiments, the SoC structure 201 includes a SoC die. In some embodiments, the SoC structure 201 includes a semiconductor active device, such as a logic SoC, logic die, logic chip, or the like. In some embodiments, the SoC structure 201 is laterally adjacent to the memory structure 202. In some embodiments, a thickness of the SoC structure 201 is substantially the same as that of the memory structure 202 which is adjacent to it. In some embodiments, an upper surface of the SoC structure 201 is substantially coplanar with an upper surface of the memory structure 202. In some embodiments, both the SoC structure 201 and the memory structure 202 are flip-chip bonded to the first side 101A of the first redistribution structure 101. In some embodiments, the memory structure 202 is a memory die. In some embodiments, the memory die includes a DRAM structure.

In some embodiments, the first redistribution structure 101 is a stack of a plurality of redistribution layers, configured to provide metal interconnects that electrically connect the SoC structure 201, the memory structure 202, or different kinds of components attached with the first redistribution structure 101 to another. In short, the formation of the redistribution layers is a process of creating a patterned metal layer on top of the dielectric layer, which redistributes the input/output (I/O) of the IC to a new location. By using these redistribution layers, it is allowed to integrate multiple dies into a single packaged structure.

Opposite to the group consisting of the SoC structure 201 and the memory structure 202, the first electronic components 301 are disposed on another side of the first redistribution structure 101 through the conductive material (e.g., conductive bumps, or the like). In some embodiments, the first electronic component 301 includes a semiconductor capacitor structure. In some embodiments, the first electronic component 301 includes a voltage converter. In some embodiments, the first electronic components 301 may include semiconductor capacitor structure or voltage converter, depending on the function requirement of the semiconductor package structure.

In some embodiments, the thicknesses of all the first electronic components 301 are identical. This structural feature of the first electronic components 301 is related to the semiconductor packaging process, which will be described later. In some embodiments, these first electronic components 301 are face-up toward the first redistribution structure 101, thus the first electronic components 301 and the SoC structure 201 and the memory structure 202 are substantially packaged in a face-to-face manner, while the first redistribution structure 101 is sandwiched there between.

Referring to FIG. 2, in some embodiments, a semiconductor package structure 11 includes a second electronic component 302 disposed on the second side 101B of the first redistribution structure 101 through the conductive material. The second electronic component 302 includes a bridge die electrically connecting the SoC structure 201 and the memory structure 202. Since the bridge die, for example, a silicon bridge die, is usually used to provide a metal connection with finer line width/space between the SoC and the memory, the option of the location of the second electronic component 302 could be different from that of the first electronic components 301. For instance, in some embodiments, the second electronic component 302 is positioned under a projective coverage of the SoC structure 201 and the memory structure 202, and so that the conductive path between the SoC structure 201 and the memory structure 202 through the second electronic component 302 (e.g., the silicon bridge die) could be as short as possible. Compared with the second electronic component 302, the location selection of the first electronic components 301 (e.g., the semiconductor capacitor structure and/or the voltage converter) is more plentiful, because there is no need to consider the length of the conductive path between the SoC structure 201 and the memory structure 202. In some embodiments, the thickness of the second electronic component 302 is substantially identical to that of the first electronic component 301, the uniformity of thicknesses between these electronic components are also related to the packaging process of semiconductor structure.

In some alternative embodiments, however, the second electronic component 302 includes a voltage converter such as a FIVR, a semiconductor capacitor such as a silicon capacitor die, or a bridge die, depending on the design of the product.

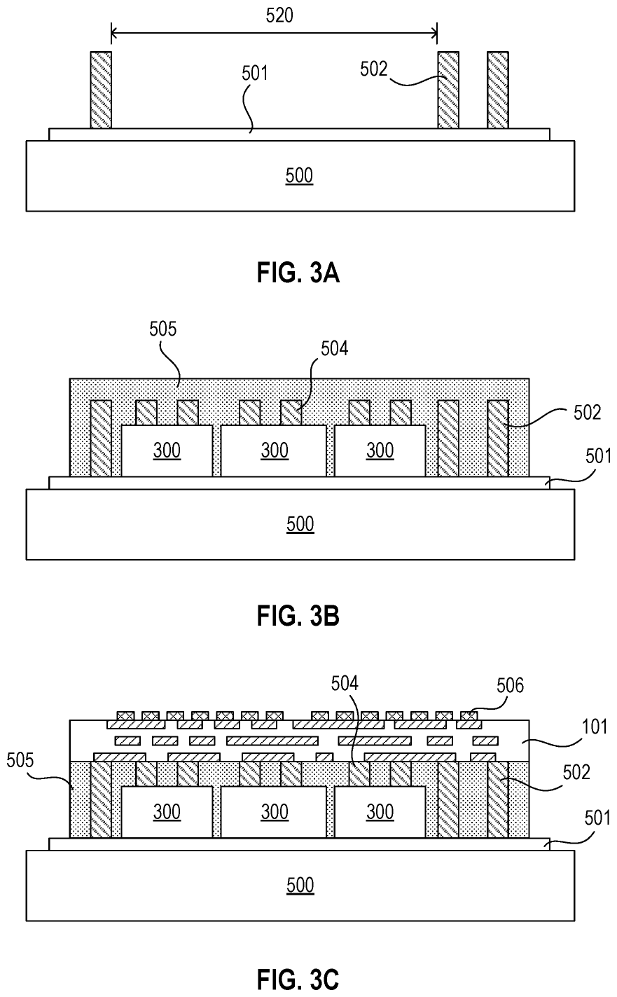

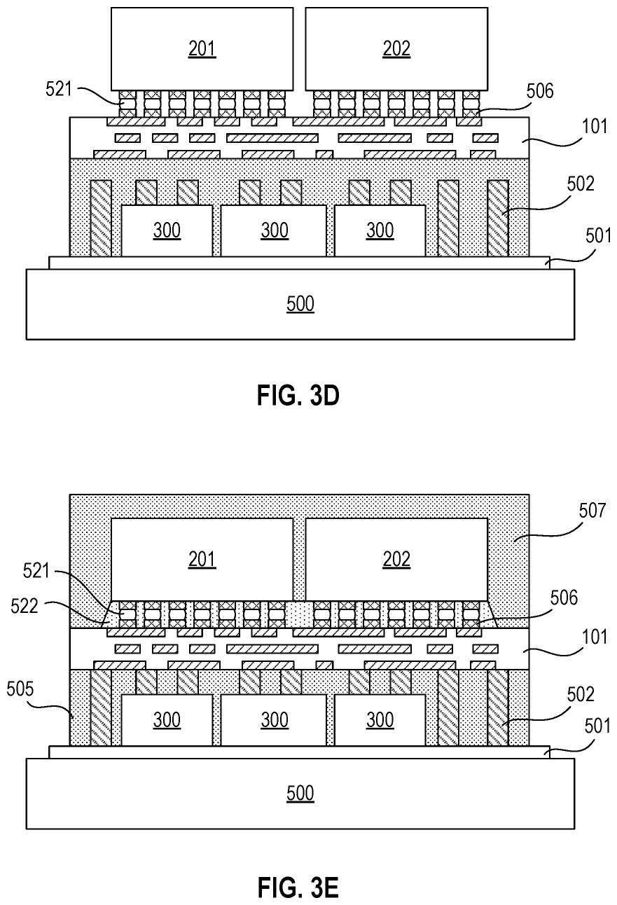

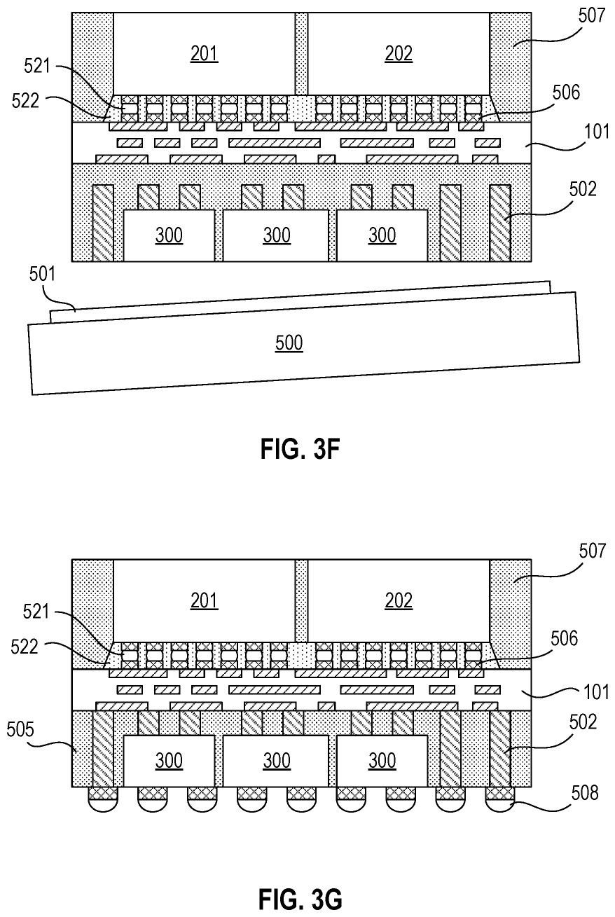

In manufacturing the semiconductor package structure 10 shown in FIG. 1 or the semiconductor package structure 11 shown in FIG. 2, the packaging process may refer to FIGS. 3A to 3G. As shown in FIG. 3A, a glass substrate 500 can be received as a carrier for supporting the semiconductor package structure during the manufacturing process. In some embodiments, a releasing layer 501 can be coated on an upper surface of the glass substrate 500. In some embodiments, an upper surface of the releasing layer 501 includes a metal pattern for electroplating. As illustrated in FIG. 3A, a plurality of metal pillars 502 can be formed on the releasing layer 501 through plating operations. In some embodiments, the metal pillars 502 includes copper. The plurality of metal pillars 502 can be arranged to space out a region for accommodating electronic components in the subsequent operations. In some embodiments, the metal pillars 502 are called through vias or conductive vias.

Referring to FIG. 3B, after the metal pillars 502 are formed on the releasing layer 501, a plurality of electronic components 300 can be placed on the releasing layer 501. The electronic components 300 can include the first electronic component 301 and the second electronic component 302. In some embodiments, the electronic components 300 are placed within the region 520 (labeled in FIG. 3A) spaced out by the metal pillars 502, and therefore the electronic components 300 are laterally surrounded by the metal pillars 502. Furthermore, in some embodiments, each of the electronic components 300 is placed in a face-up manner, which means that the conductive pads of the electronic components 300 are facing the direction opposite to the releasing layer 501. The releasing layer 501 is in contact with the back side of the electronic components 300, which may only have TSVs penetrating the substrate of the electronic components 300 or may be free from conductive pads for electronic connections. In some embodiments, the thickness/height of each of the electronic components 300 is thinner than the height of the metal pillars 502. As shown in the FIG. 3B, a plurality of electrode structures 504 can be formed on the electronic components 300 to extend the conductive pads of the electronic components 300 to be align with the metal pillars 502. In other words, the upper ends of the metal pillars 502 are coplanar with the upper ends of the electrode structures 504. After the electronic components 300 are placed and the electrode structures 504 are formed thereon, a molding operation can be performed to encapsulate the electronic components 300, the metal pillars 502, and the electrode structures 504 over the releasing layer 501 by a first encapsulation layer 505. In some embodiments, the first encapsulation layer 505 includes molding material such as epoxy molding compound (EMC). In some embodiments, the first encapsulation layer may laterally space the electronic components (e.g., the first and the second electronic components 301, 302) apart.

Accordingly, as previously shown in FIGS. 1 and 2, there are a plurality of through vias (i.e., the metal pillars 502) in the first encapsulation layer 505, wherein at least one of the first electronic component 301 or the second electronic component 302 are laterally surrounded by the plurality of through vias in the first encapsulation layer 505.

Referring to FIG. 3C, in some embodiments, the first encapsulation layer 505 is grinded to expose the upper ends of the metal pillars 502 and the upper ends of the electrode structures 504. Next, the first redistribution structure 101 is formed over the grinded molding material, while the conductive interconnects of the first redistribution structure 101 are coupled with the upper ends of the metal pillars 502 and the upper ends of the electrode structures 504. Accordingly, the chips or dies later bonded over the first redistribution structure 101 can thus electrically connect to the electronic components 300 and the metal pillars 502 through the first redistribution structure 101.

Still referring to FIG. 3C, in some embodiments, after the first redistribution structure 101 is formed, a plurality of bump pad structures 506 can be formed over the first redistribution structure 101 subsequently. These bump pad structures 506 are configured to bond with the chips or dies mounted over the first redistribution structure 101.

Referring to FIG. 3D, in some embodiments, the SoC structure 201 and the memory structure 202 can be bonded over the first redistribution structure 101 in a flipped manner. In some embodiments, a plurality of micro bumps 521 can be utilized to electrically connect the bonded chips or dies, e.g., the SoC structure 201 and the memory structure 202, with the first redistribution structure 101, and therefore the bonded chips or dies can electrically communicate with the electronic components 300 below the first redistribution structure 101.

Referring to FIG. 3E, in some embodiments, an underfill 522 can be applied to the bump pad structures 506 and the micro bumps 521 below the SoC structure 201 and the memory structure 202 through a reflow operation. The underfill 522 is typically a polymer or liquid epoxy. Then, another molding operation can be performed to encapsulate the SoC structure 201 and the memory structure 202 over the first redistribution structure 101 by a second encapsulation layer 507. In some embodiments, the second encapsulation layer 507 includes molding material such as EMC.

Referring to FIG. 3F, in some embodiments, the second encapsulation layer 507 is grinded to thin down the thickness thereof. The second encapsulation layer 507 can be thinned down to expose the upper surface of the SoC structure 201 and/or the upper surface of the memory structure 202, depending on the thicknesses of the SoC structure 201 and the memory structure 202. Next, the glass substrate 500 and the releasing layer 501 can be removed through a de-bonding operation, and a lower end of each metal pillar 502 and a surface of each electronic component 300 are thus exposed from the first encapsulation layer 505.

Referring to FIG. 3G, in some embodiments, a bump plating operation can be performed to form a plurality of bumping structures 508 at least in contact with the metal pillars 502. The bumping structures 508 includes conductive terminals such as micro bumps, C4 bumps, solder balls, or the like. In the scenario that some electronic components 300 may have TSVs to provide electrical connection in proximity to the lower side thereof, the bumping structures 508 can be formed to in contact with these electronic components 300 as well.

In some embodiments, the manufacturing of the semiconductor package structure shown in FIGS. 3A to 3G is a wafer-level packaging process, hence, the semiconductor package structure shown in the figures are only a portion of the whole wafer. After the SoC structure 201 and the memory structure 202 are properly packaged with the electronic components 300, the wafer, which having a large number of these structures/components, can be sliced into individual dices. In some embodiments, the wafer can be transferred to a dicing tape to be diced through a die saw process.

As mentioned previously, some electronic components 300 may have TSVs to provide electrical connection in proximity to the lower side thereof. To be more detailed, in the case of the electronic component 300 is the bridge die, such bridge die is usually free from TSVs since the bridge die is mainly providing metal connections between the SoC structure 201 and the memory structure 202. However, different from the scenario of bridge die, in the case of the electronic component 300 includes semiconductor capacitor structure or voltage converter (e.g., the FIVR), there could be TSVs in the electronic component 300.

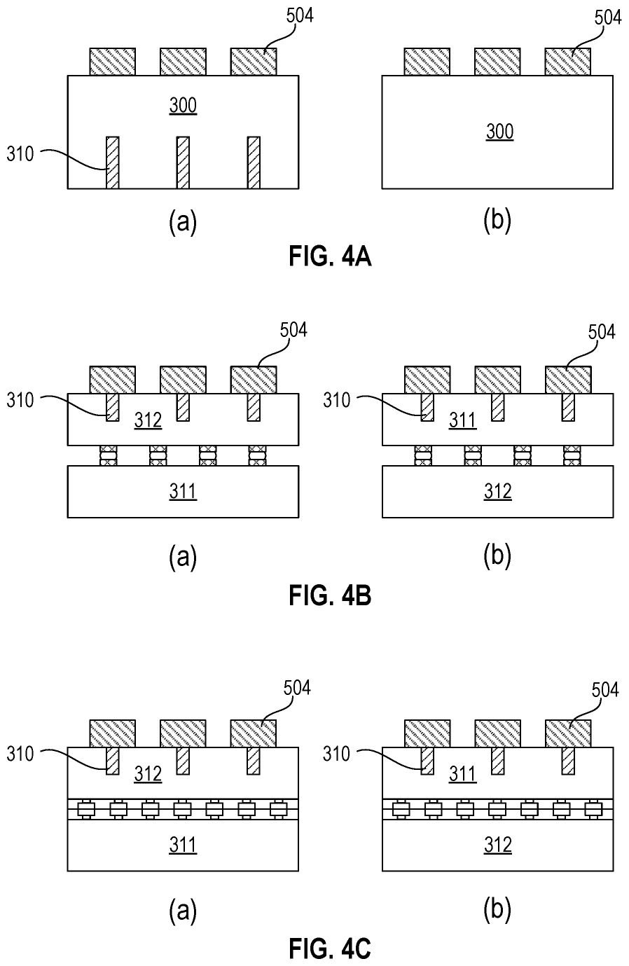

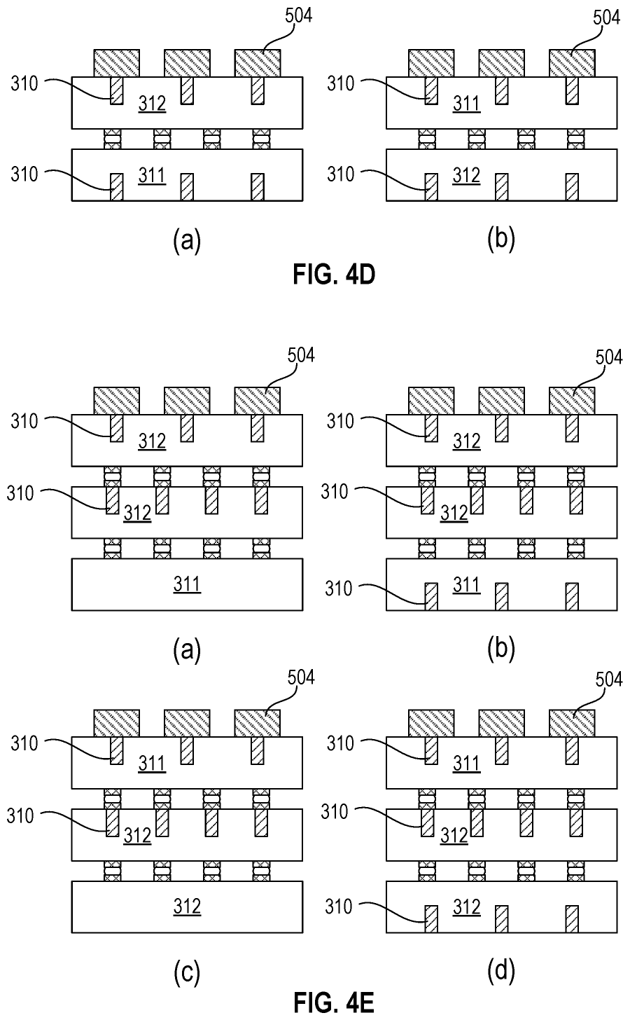

For instance, in FIG. 4A, if the electronic component 300 is a voltage converter, which has an active device and a semiconductor capacitor structure, the semiconductor capacitor structure can be integrated into the active device either with TSV 310 (as shown in FIG. 4A (a)) or without TSV (as shown in FIG. 4A (b)). In some embodiments, the voltage converter includes a power management die and a silicon capacitor die. In some embodiments, the active device is a power management unit. In some embodiments, the voltage converter is substantially a PMIC active device.

In FIG. 4B, the silicon capacitor 312 can be stacked over the PMIC active device 311 in the electronic component 300 (as shown in FIG. 4B (a)), or alternatively, the PMIC active device 311 can be stacked over the silicon capacitor 312 (as shown in FIG. 4B (b)). In some embodiments, the silicon capacitor 312 is a semiconductor capacitor, such as a silicon capacitor die. In some embodiment, the TSV is positioned at least in one of the PMIC active device 311 (e.g., a power management die) or the silicon capacitor 312 (e.g., a silicon capacitor die).

The TSVs 310 are presented in the simplified examples shown in the figures, as they terminate at some point of the PMIC active device 311 and the silicon capacitor 312. This is because the TSVs 310 in the PMIC active device 311 and the silicon capacitor 312 are conductive through vias that penetrate the PMIC active device 311 or the silicon capacitor 312 from one side to a metallization structure (e.g., BEOL structure) thereof.

Instead of using the micro bump bonding technique shown in FIG. 4B, as shown in FIG. 4C, in some embodiments, a hybrid bonding structure 313 can be used to connect the PMIC active device 311 and the silicon capacitor 312 in the electronic component 300.

In some embodiments, the TSVs 310 may be created in either the PMIC active device 311 or the silicon capacitor 312 for external connections, as shown in FIG. 4D. This means that the TSVs 310 can be used to electrically connect to the bumping structures 508, which were previously shown in FIG. 3G, by placing the TSVs 310 in proximity to the side opposite to the side with electrode structures 504. In other embodiments, the micro-bumping structure depicted in FIG. 4D can be substituted with the hybrid bonding structures for connecting the PMIC active device 311 and the silicon capacitor 312 in the electronic component 300, as illustrated in the previous embodiment shown in FIG. 4C.

Additionally, referring to FIG. 4E, in some embodiments, a plurality of silicon capacitors 312 can be stacked with the PMIC active device 311. As illustrated in FIGS. 4E (a) and 4E (b), each of the silicon capacitors 312 may have TSVs 310 for electrical connection within the electronic component 300, wherein the PMIC active device 311 located near the bottom of the electronic component 300 may or may not include TSVs 310 for external connections. Alternatively, as illustrated in FIGS. 4E (c) and 4E (d), the PMIC active device 311 can be positioned near the top of the electronic component 300, while the silicon capacitor 312 near the bottom of the electronic component 300 may or may not include TSVs 310 for external connections. In alternative embodiments, the micro-bumping structure depicted in FIG. 4E may be substituted with hybrid bonding structures for connecting the PMIC active device 311 and the silicon capacitor 312, or for connecting adjacent silicon capacitors 312 within the electronic component 300, as illustrated in the previous embodiment shown in FIG. 4C.

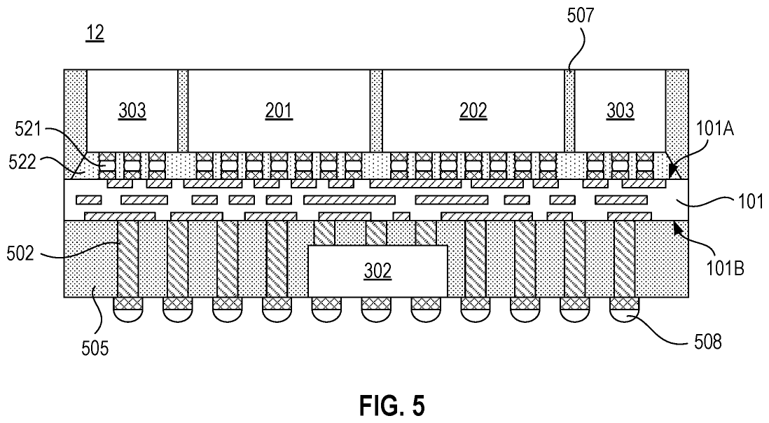

Referring to the semiconductor package structure 12 in FIG. 5, in some embodiments, the electronic components can be placed separately on different sides of the first redistribution structure 101. For instance, as shown in the figure, at least a third electronic components 303 can be placed on the first side 101A of the first redistribution structure 101, while being adjacent to the SoC structure 201 or the memory structure 202. The third electronic component 303 is electrically connected to at least one of the SoC structure 201 or the memory structure 202 through the first redistribution structure 101. In some embodiments, the group of the SoC structure 201 and the memory structure 202 can be surrounded laterally by the third electronic components 303.

In some embodiments of the present disclosure, the third electronic components 303 can be placed on the first side 101A of the first redistribution structure 101 in any embodiments that the SoC structure 201 and the memory structure 202 are laterally arranged.

In some embodiments, the third electronic component 303 includes a semiconductor capacitor structure (e.g., the silicon capacitor die) or a voltage converter (e.g., the FIVR). In some embodiments, a vertical projection of the third electronic component 303 on the first redistribution structure 101 is non-overlapping with a vertical projection of the first electronic component 301. In the present disclosure, the nature of the first electronic component 301 and the third electronic component 303 are substantially the same, while these electronic components are disposed in different sides of the redistribution structure in different embodiments.

Other than the third electronic components 303 placed on the first side 101A, some electronic components (e.g., the first electronic component 301 and the second electronic components 302) can still be placed on the second side 101B of the first redistribution structure 101. Since the second electronic components 302 can include silicon bridge die, if an electronic component is placed on the second side 101B of the first redistribution structure 101, particularly, under a projective coverage of the SoC structure 201 and the memory structure 202, such electronic component is the second electronic components 302 with silicon bridge die. In some embodiments, the second electronic components 302 placed on the second side 101B of the first redistribution structure 101 may also include a silicon capacitor die.

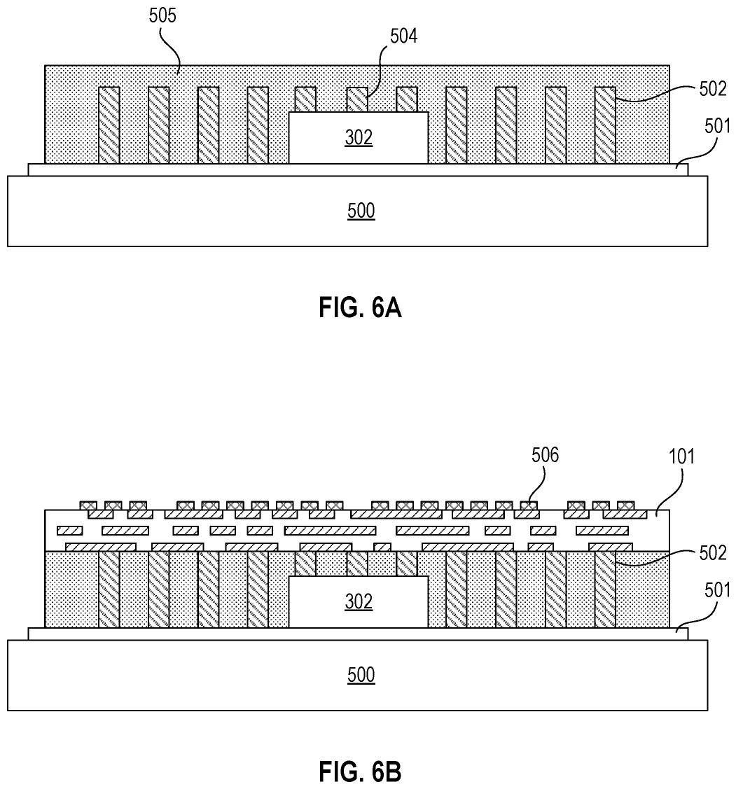

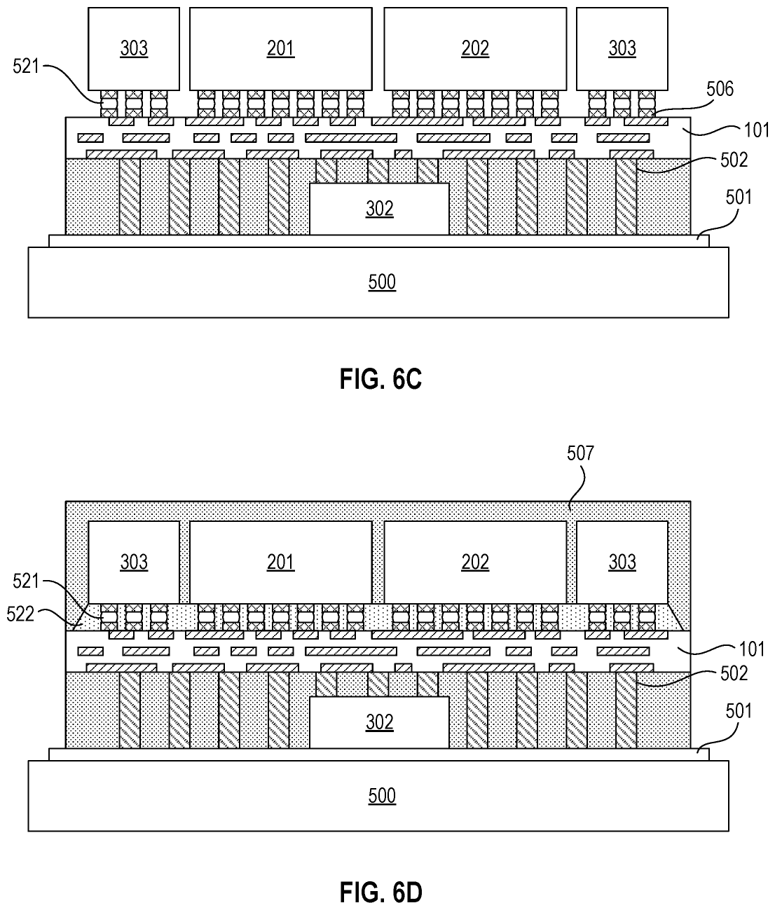

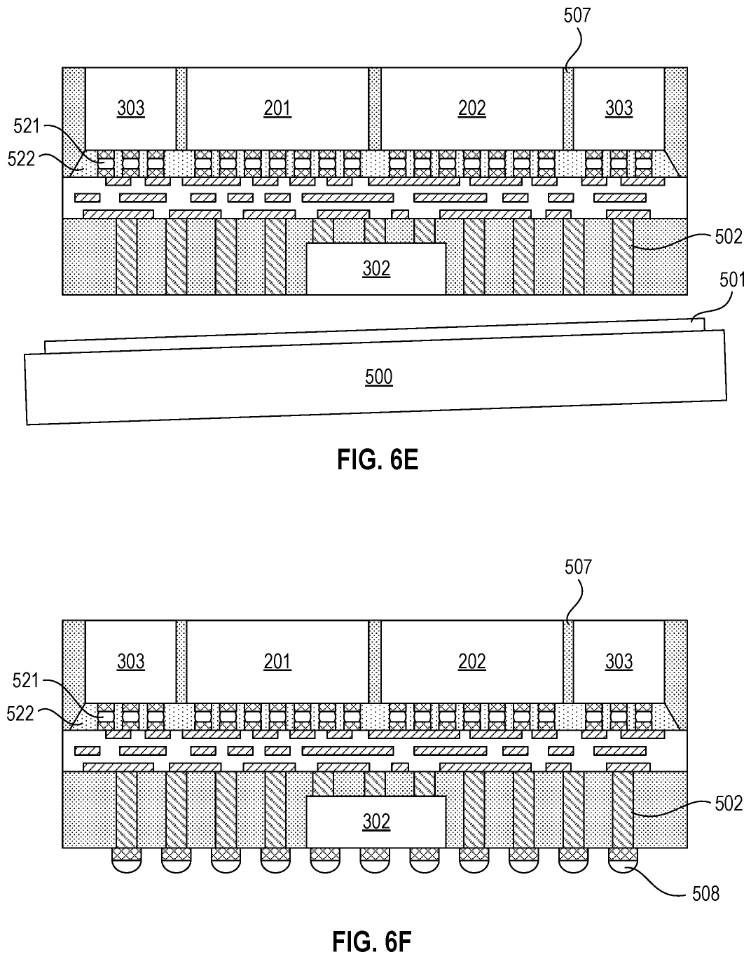

In manufacturing the semiconductor package structure 12 as shown in FIG. 5, it may refer to FIGS. 6A to 6F. The preparation of the glass substrate 500, the releasing layer 501, and the metal pillars 502 may refer to the disclosure of FIG. 3A, and omitted here for brevity.

Referring to FIGS. 6A and 6B, after the metal pillars 502 are formed on the releasing layer 501, the second electronic components 302 can be placed on the releasing layer 501. In some embodiments, the second electronic components 302 is placed within the region spaced out by the metal pillars 502, and therefore the second electronic components 302 is laterally surrounded by the metal pillars 502. In some embodiments, the second electronic components 302 is placed in a face-up manner, which means that the conductive pads of the second electronic components 302 is facing the direction opposite to the releasing layer 501. In some embodiments, the thickness/height of the second electronic components 302 is thinner than the height of the metal pillars 502. In some embodiments, the electrode structures 504 can be formed on the second electronic components 302 to extend the conductive pads of the second electronic components 302 to be align with the metal pillars 502. After the second electronic components 302 is placed and the electrode structures 504 are formed thereon, a molding operation can be performed to encapsulate the second electronic components 302, the metal pillars 502, and the electrode structures 504 over the releasing layer 501 by the first encapsulation layer 505.

The details of grinding the first encapsulation layer 505 and the formation of the first redistribution structure 101 in this embodiment is substantially identical to those in FIG. 3C, and omitted here for brevity.

Referring to FIG. 6C, in some embodiments, a plurality of third electronic components 303, the SoC structure 201, and the memory structure 202 are bonded in a flipped manner over the first redistribution structure 101. The SoC structure 201 and the memory structure 202 are electrically communicate with the second electronic components 302 and the third electronic component 303 through micro bumps and the first redistribution structure 101 below. This embodiment differs from the one previously shown in FIG. 3D, where the first electronic components 301 were placed on the releasing layer 501 before forming the first redistribution structure 101.

The details of utilizing the underfill, the second molding operation, the second grinding operation, the de-bonding of the glass substrate, and the bump plating operation illustrated in FIGS. 6D to 6F are substantially identical to those in FIGS. 3E to 3G, and omitted here for brevity. After the SoC structure 201 and the memory structure 202 are properly packaged with the second electronic component 302 and the third electronic components 303, the wafer, which having a large number of these structures/components, can be sliced into individual dices subsequently.

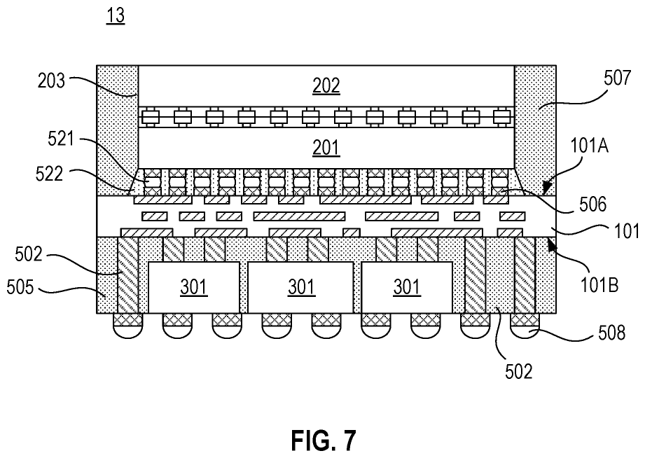

In some embodiments, the SoC structure 201 is vertically stacked to the memory structure 202. Referring to FIG. 7, for instance, the memory structure 202 can be stacked over the SoC structure 201, instead of arranged laterally thereto. In such embodiments, the semiconductor package structure 13 may occupy less area by utilizing vertical space. Furthermore, since the upper side of the SoC structure 201 is covered by the memory structure 202, such structure is more suitable for applications that include additional thermal design or have a relatively low power-consuming SoC structure. In some embodiments, the memory structure 202 is bonded over the SoC structure 201 by the hybrid bonding structure. In some embodiments, the memory structure 202 is bonded over the SoC structure 201 by the micro bumps. In some embodiments, the stack of the SoC structure 201 and the memory structure 202 is formed under the wafer on wafer (WoW) or chip on wafer (CoW) technique.

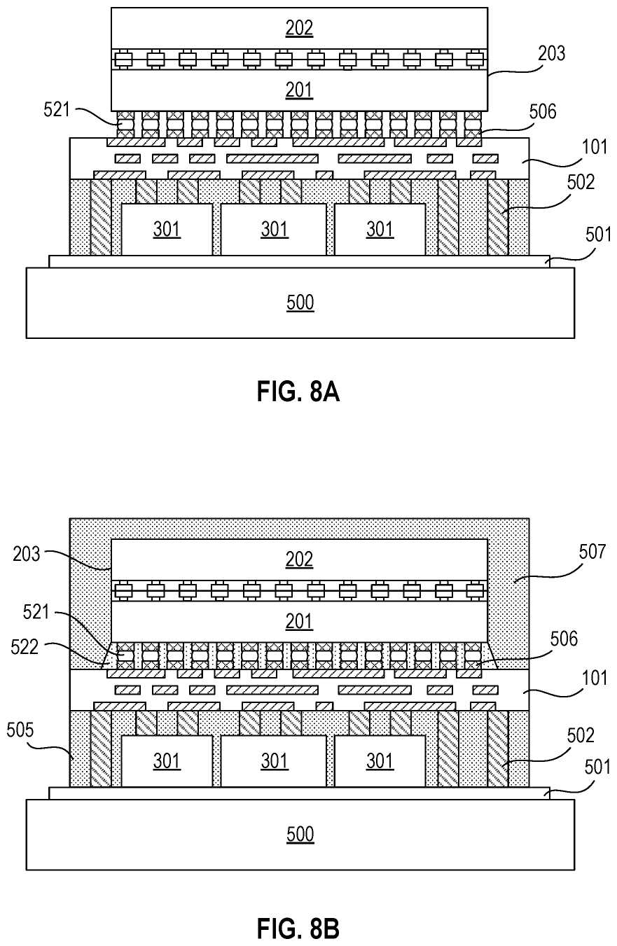

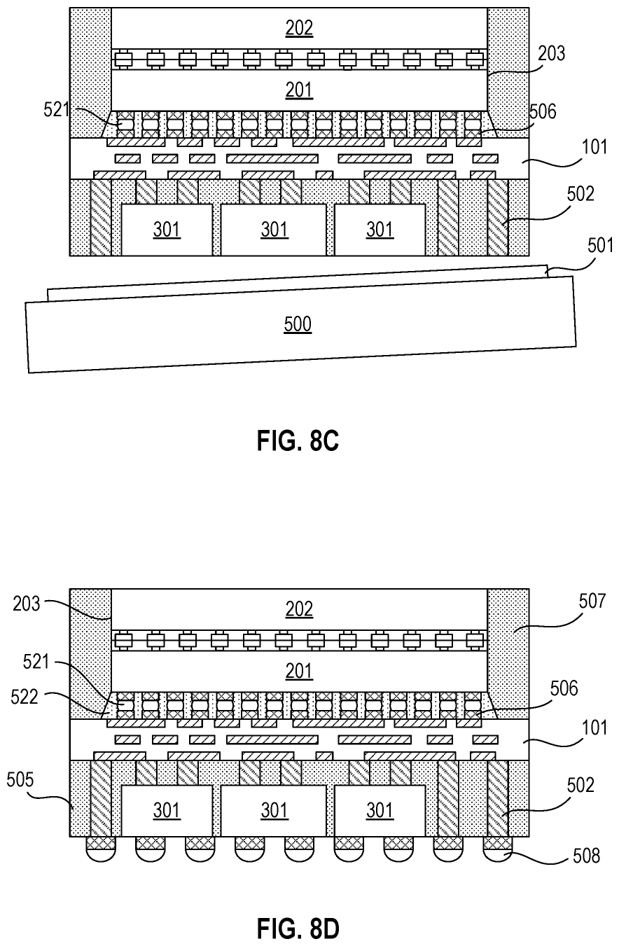

In manufacturing the semiconductor package structure 13 as shown in FIG. 7, it may refer to FIGS. 8A to 8D. The operations before the forming of the first redistribution structure 101 and the bump pad structure 506 may refer to the disclosure of FIGS. 3A to 3C, and omitted here for brevity.

Referring to FIG. 8A, after the bump pad structures 506 are formed over the second side 101B of the first redistribution structure 101, an integrated SoC die 203 having the SoC structure 201 and the memory structure 202 can be bonded over the bump pad structures 506. Compared with the memory structure 202 in the integrated SoC die 203, the SoC structure 201 in the integrated SoC die 203 is closer to the bump pad structures 506.

Next, as illustrated in FIG. 8B, the bump pad structures 506 below the integrated SoC die 203 are applied by underfill through a reflow operation. Then, the integrated SoC die 203 is encapsulated by the second encapsulation layer 507. Subsequently, the second encapsulation layer 507 is grinded to thin down to expose the upper surface of the memory structure 202 in the integrated SoC die 203. In some embodiments, the manufacturing of the semiconductor package structure depicted in FIGS. 8A to 8D is manufactured through a wafer-level packaging process, and therefore the aforementioned integrated SoC die 203 is a bonded wafer that has a memory wafer bonded over a SoC wafer.

The details of the de-bonding of the glass substrate and the bump plating operation illustrated in FIGS. 8C and 8D are substantially identical to those in FIGS. 3F and 3G, and omitted here for brevity. After the stack of the SoC structure 201 and the memory structure 202 are properly packaged with the first electronic components 301 at different sides of the first redistribution structure 101, the wafer, which having a large number of these structures/components, can be sliced into individual dices subsequently.

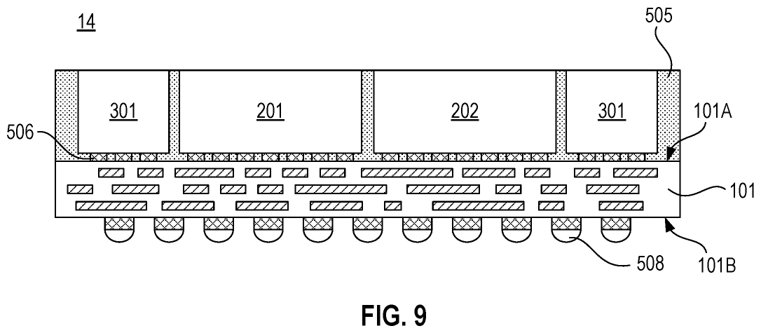

Referring to FIG. 9, in some embodiments, the first electronic components 301 are packaged with the SoC structure 201 and the memory structure 202 laterally in the semiconductor package structure 14. Furthermore, there are no other electronic components packaged with these structures through a redistribution structure in between them. In such embodiments, the thickness of the semiconductor package structure 14 is relatively thinner than that of the semiconductor package structures 10, 11, 12, and 13 as previously shown in FIGS. 1, 2, 5, and 7, because there is no electronic component vertically arranged with the SoC structure 201 and the memory structure 202. In such embodiments, all the first electronic components 301, the SoC structure 201 and the memory structure 202 are placed on the first side 101A of the first redistribution structure 101. In some embodiments, the semiconductor package structure 14 is free from a silicon bridge die, since there is no second electronic component 302 placed on the second side 101B of the first redistribution structure 101. Besides, the function of the silicon bridge die can be performed by the metal connections in the first redistribution structure 101. Like in the previous embodiments, the first electronic components 301 includes silicon capacitor dies or FIVRs.

Still referring to FIG. 9, in some embodiments, the thicknesses of the first electronic components 301, the SoC structure 201, and the memory structure 202 are the same, thus the upper surfaces of the first electronic components 301, the SoC structure 201, and the memory structure 202 are coplanar with each other. In some embodiments, the first encapsulation layer 505 laterally spaces the first electronic component 301 and one of the SoC structure 201 or memory structure 202 apart.

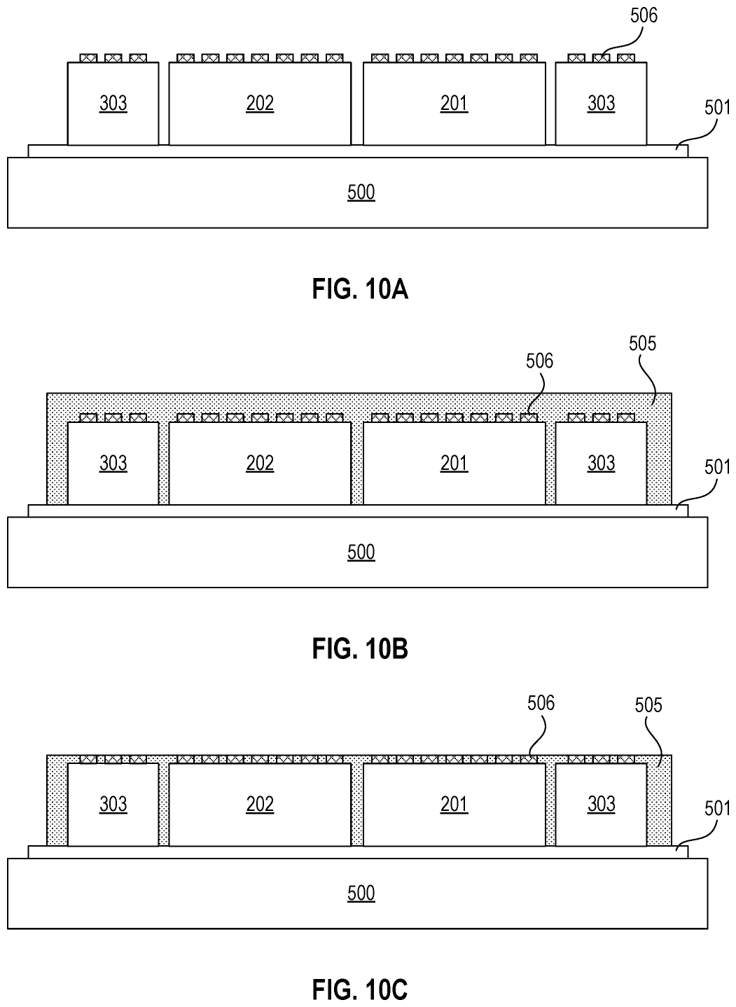

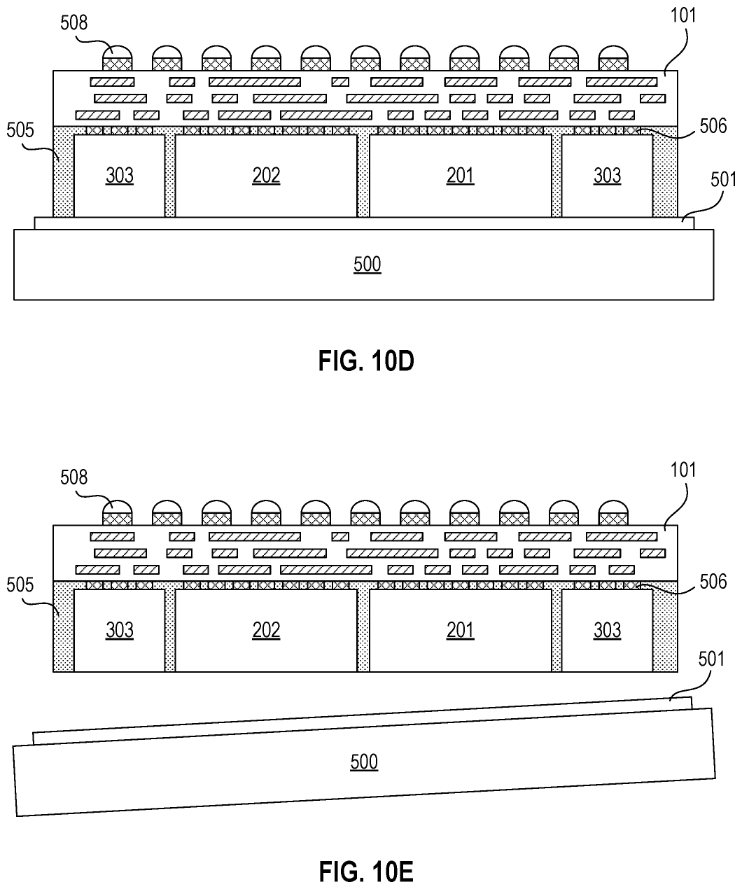

In manufacturing the semiconductor package structure 14 as shown in FIG. 9, the process may refer to FIGS. 10A to 10E. As shown in FIG. 10A, the glass substrate 500 can be received as a carrier for supporting the semiconductor package structure during the manufacturing process. In some embodiments, the releasing layer 501 may be applied to the upper surface of the glass substrate 500. Unlike previous embodiments, there is no need to form the metal pillars 502 on the releasing layer 501 in this embodiment, resulting in no metal pattern on the upper surface of the releasing layer 501.

Next, a plurality of first electronic components 301, the SoC structure 201, and the memory structure 202 are placed on the releasing layer 501 in a face-up manner. In some embodiments, the first electronic components 301 are placed in proximity to a surrounding region over the releasing layer 501, so that the SoC structure 201, and the memory structure 202 are laterally surrounded by the first electronic components 301. Then, a plurality of bump pad structures 506 can be formed over the first electronic components 301, the SoC structure 201, and the memory structure 202, configured to bond the electronic components or structures with the first redistribution structure 101. In some embodiments, the bump pad structures 506 in this embodiment is substantially identical to the electrode structures 504 shown in previous embodiments since these structures are both utilized for bumping.

As shown in FIG. 10B, after placing the first electronic components 301, the SoC structure 201, and the memory structure 202, and forming the bump pad structures 506 on them, a molding operation be performed to encapsulate these components and structures with the first encapsulation layer 505.

In some embodiments, the first encapsulation layer 505 is subsequently ground in a grinding operation, and the upper surface of the bump pad structures 506 are exposed thereby, as depicted in FIG. 10C.

Once the bump pad structures 506 are exposed, the first redistribution structure 101 is formed over the bump pad structures 506, as shown in FIG. 10D. In some embodiments, a bump plating operation can be performed to form the bumping structures 508 for external connection. The glass substrate 500 and the releasing layer 501 can be removed through a de-bonding operation, as illustrated in FIG. 10E. After properly packaging the lateral-arranged first electronic components 301, the SoC structure 201, and the memory structure 202 on a single side of the first redistribution structure 101, the wafer, which contains a large number of these structures/components, can be sliced into individual dice subsequently.

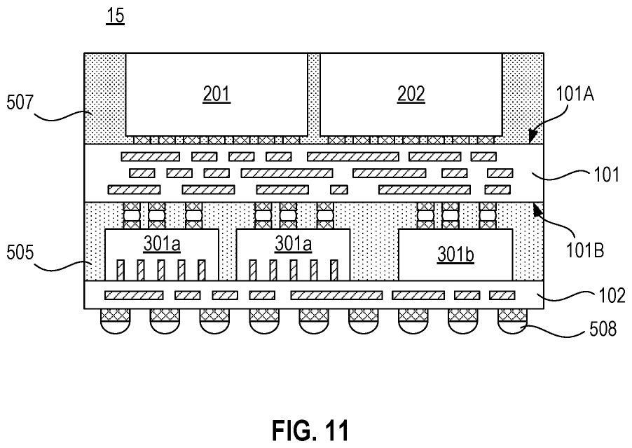

Referring to the semiconductor package structure 15 shown in FIG. 11, in some embodiments, which differ from the semiconductor package structure 10 previously shown in FIG. 1, the semiconductor package structure 15 may be free from the metal pillars 502 formed near the first electronic components 301a, 301b below the first redistribution structure 101 in the semiconductor package structure 15. Furthermore, the electronic components 300 of the semiconductor package structure 15 are encapsulated by a molding material that includes molded underfill (MUF) instead of EMC. Moreover, the first electronic components 301a are the electronic components that may have TSVs, whereas the first electronic component 301b is the electronic component may without TSVs. In some embodiments, the TSVs in the first electronic components 301a are electrically connecting the first redistribution structure 101 and a second redistribution structure 102. More details regarding the TSVs in the electronic components may refer to the examples illustrated in FIGS. 4A to 4E. In some embodiments, the first electronic components 301a are supported by the second redistribution structure 102, and the second redistribution structure 102 is electrically connected to the first redistribution structure 101 by the TSVs in the first electronic components 301a.

In addition, in some embodiments, at least one of the first electronic components 301a, 301b in FIG. 11 can be replaced with the second electronic components, so that the second redistribution structure 102 in the semiconductor package structure 15 may electrically couple to the first electronic component(s) and the second electronic component(s). In some embodiments, the second redistribution structure 102 is disposed on a side of the first electronic component 301a, 301b facing away from the first redistribution structure 101.

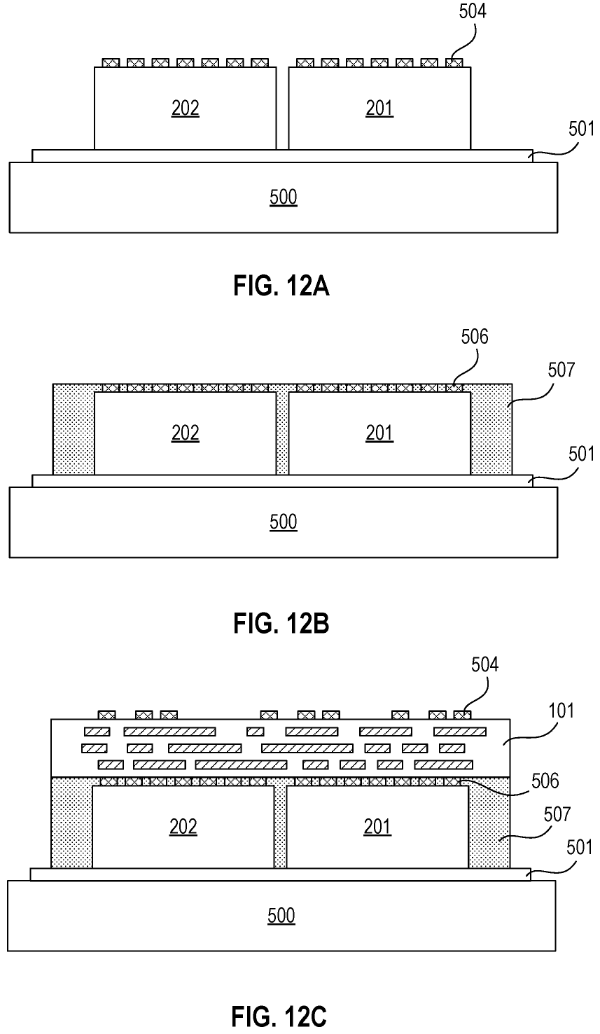

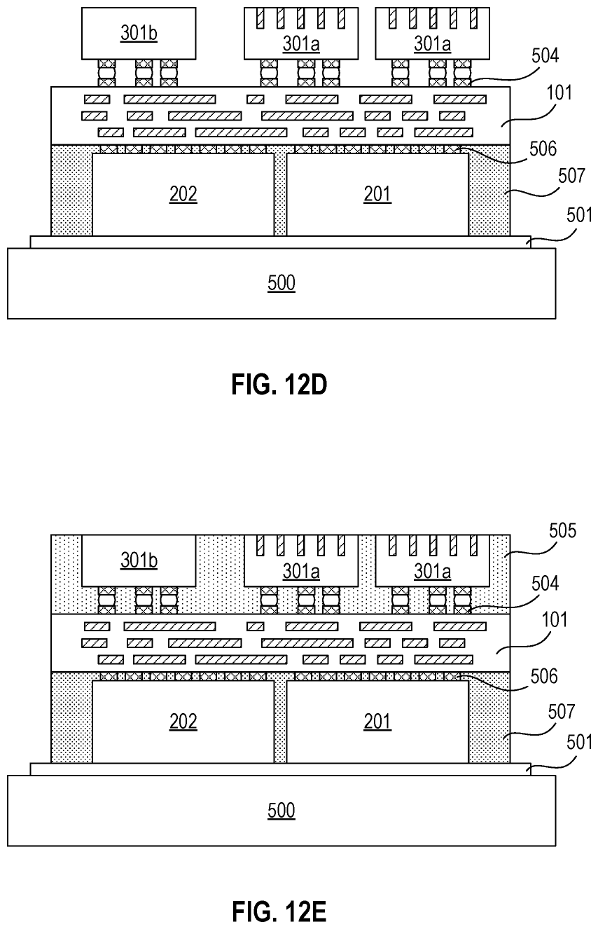

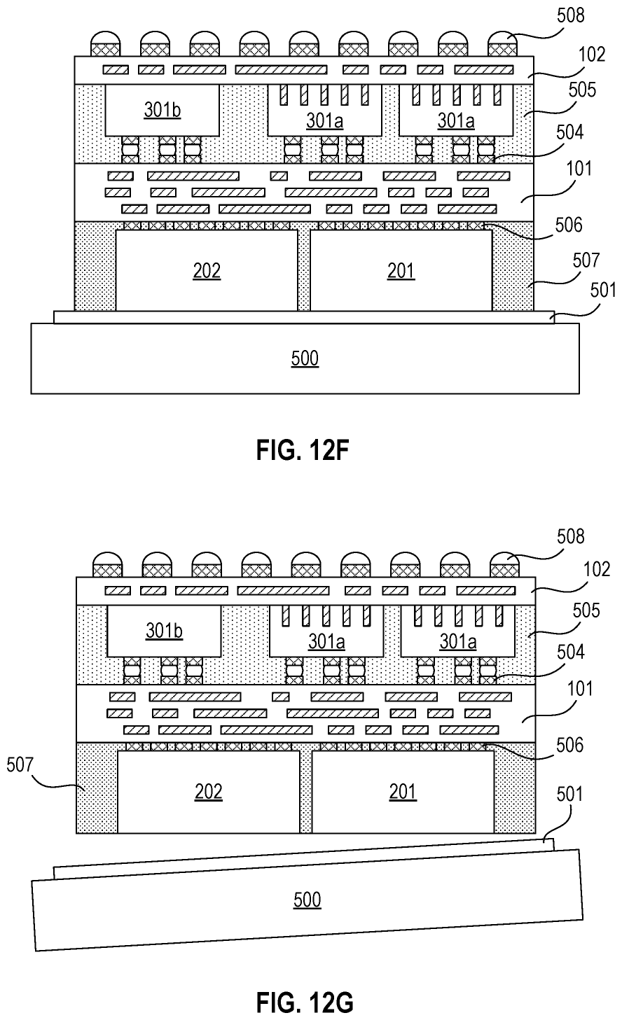

In manufacturing the semiconductor package structure 15 as shown in FIG. 11, the process may refer to the process in FIGS. 12A to 12G. As shown in FIG. 12A, the glass substrate 500 can be received as a carrier for supporting the semiconductor package structure during the manufacturing process. In some embodiments, the releasing layer 501 may be applied to the upper surface of the glass substrate 500. Like the embodiment shown in FIG. 10A, there is no need to form the metal pillars 502 on the releasing layer 501 in this embodiment, resulting in no metal pattern on the upper surface of the releasing layer 501.

Next, the SoC structure 201 and the memory structure 202 are placed on the releasing layer 501 in a face-up manner. Then, a plurality of bump pad structures 506 can be formed over the SoC structure 201 and the memory structure 202, configured to bond the electronic components or structures with the first redistribution structure 101.

The operations of forming and grinding the second encapsulation layer 507, forming the first redistribution structure 101, and performing the bump plating operation shown in FIGS. 12B and 12C are substantially identical to the forming and grinding the first encapsulation layer 505 and the bump plating operation in FIGS. 10C and 10D, and omitted here for brevity. That is, there are two encapsulation layers in the semiconductor package structure 15, while the semiconductor package structure 14 only has one, and the second encapsulation layer 507 in the semiconductor package structure 15 is corresponding to the first encapsulation layer 505 in the semiconductor package structure 14, which are at least configured to encapsulate the electronic components, e.g., the first electronic components 301 in FIG. 9 and the first electronic components 301a, 301b in FIG. 11.

Referring to FIG. 12D, in some embodiments, the first electronic components 301a, 301b can be bonded to the electrode structures 504 using the flip-chip bonding technique. In some embodiments, these first electronic components 301a, 301b may include silicon bridge die, semiconductor capacitor structure, or voltage converter, depending on the product's design requirements.

Referring to FIG. 12E, in some embodiments, the electrode structures 504 and electronic components 300 can be encapsulated in a single operation using MUF as the first encapsulation layer 505. The high fluidity of MUF may surround the electrode structures 504 and first electronic components 301a, 301b, while the upper surface of the first encapsulation layer 505 aligns with that of the first electronic components 301a, 301b. Accordingly, the utilizing of MUF as the first encapsulation layer 505 may eliminate the need for a grinding operation to expose the upper surface of the first electronic components 301a, 301b. This ensures that the TSVs near the upper surface of the first electronic components 301a remain undamaged after the encapsulation process.

Referring to FIG. 12F, after the encapsulation of the first electronic components 301a, 301b, the second redistribution structure 102 is formed over the first electronic components 301a, 301b and the first encapsulation layer 505. In some embodiments, a bump plating operation can be performed to form the bumping structures 508 for external connection.

Referring to FIG. 12G, the glass substrate 500 and the releasing layer 501 can be removed through a de-bonding operation, subsequently. After properly packaging the first electronic components 301a, 301b at a side of the first redistribution structure 101 opposite to the SoC structure 201 and the memory structure 202, the wafer, which contains a large number of these structures/components, can be sliced into individual dice.

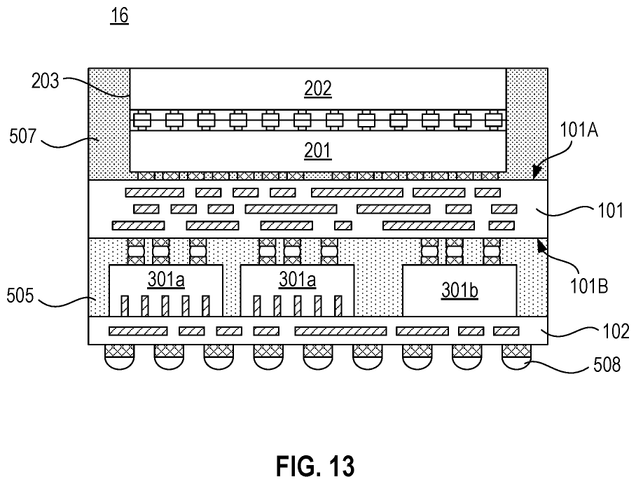

As shown in FIG. 13, in some embodiments, the semiconductor package structure 16 may have two redistribution structures as the embodiment previously shown in FIG. 11, whereas the memory structure 202 is stacked over the SoC structure 201. The stack of the SoC structure 201 and the memory structure 202 may refer to the embodiment previously shown in FIG. 7.

In such embodiments, the semiconductor package structure 16 may occupy less area by utilizing vertical space. Furthermore, since the upper side of the SoC structure 201 is covered by the memory structure 202, such structure is more suitable for applications that include additional thermal design or have a relatively low power-consuming SoC structure. In some embodiments, the memory structure 202 is bonded over the SoC structure 201 by the hybrid bonding structure. In some embodiments, the memory structure 202 is bonded over the SoC structure 201 by the micro bumps. In some embodiments, the stack of the SoC structure 201 and the memory structure 202 is formed under the wafer on wafer (WoW) or chip on wafer (CoW) technique. Furthermore, since the memory structure 202 is not laterally placed with the SoC structure 201, the memory structure 202 is free from in direct contact with any redistribution structure in these embodiments.

Similar with the embodiments shown in FIG. 11, the first electronic components 301a in FIG. 13 are the electronic components that may have TSVs, whereas the first electronic component 301b is the electronic component may without TSVs. In some embodiments, the TSVs in the first electronic components 301a are electrically connecting the first redistribution structure 101 and the second redistribution structure 102. In addition, in some embodiments, at least one of the first electronic components 301a, 301b in FIG. 13 can be replaced with the second electronic components, so that the second redistribution structure 102 in the semiconductor package structure 16 may electrically couple to the first electronic component(s) and the second electronic component(s). In some embodiments, the second redistribution structure 102 is disposed on a side of the first electronic component 301a, 301b facing away from the first redistribution structure 101.

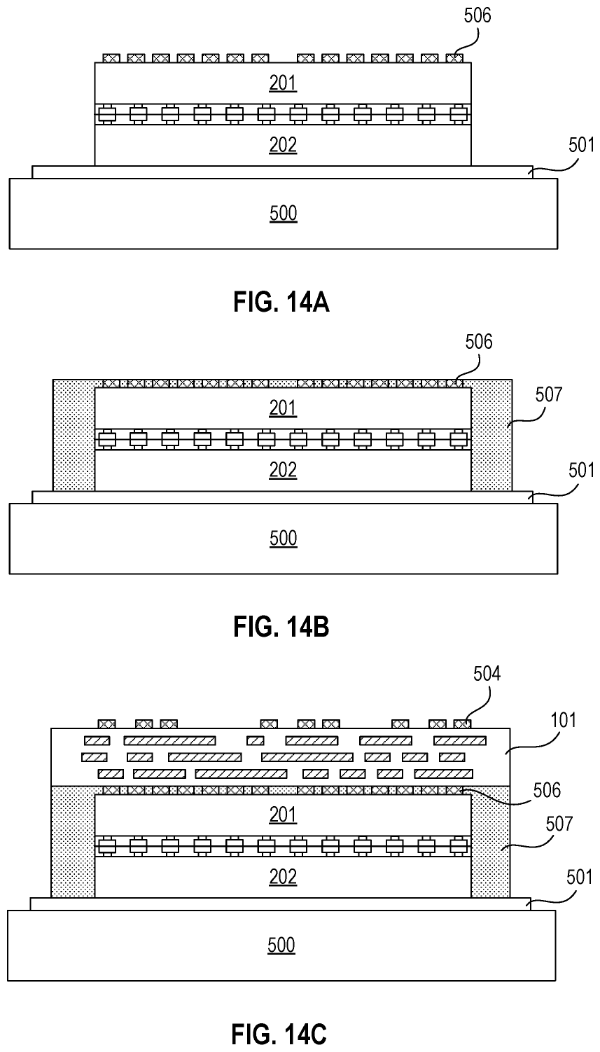

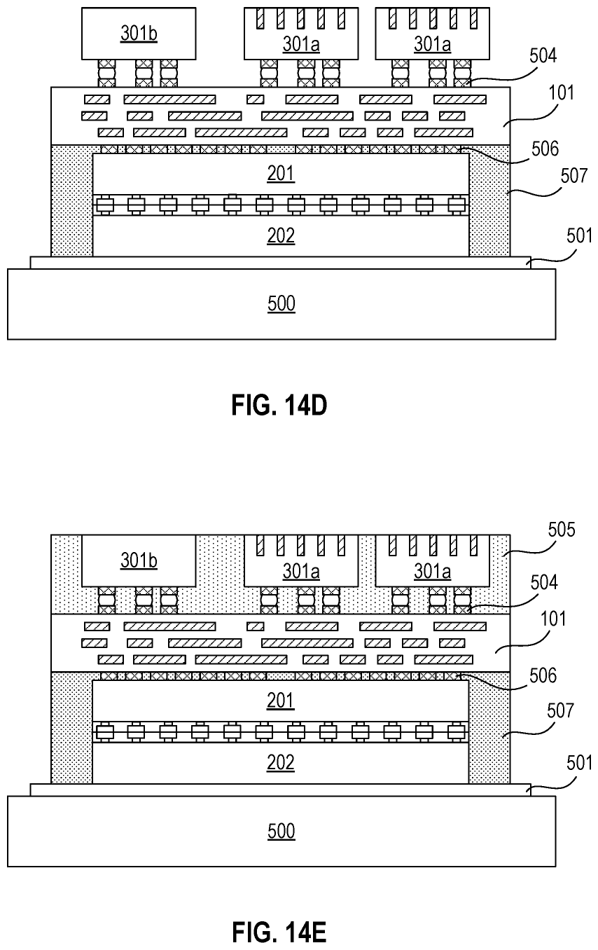

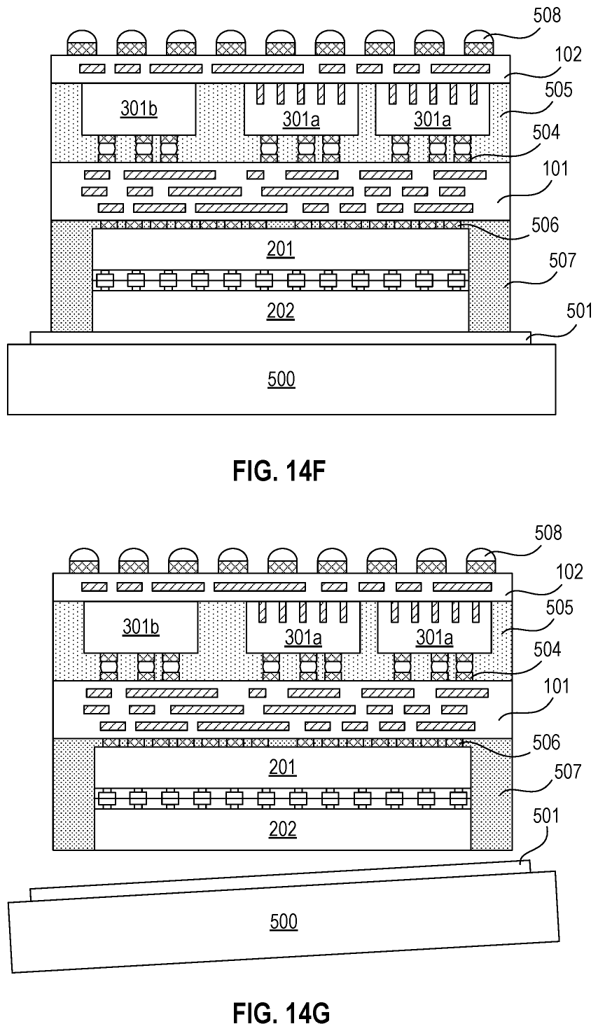

In manufacturing the semiconductor package structure 16 as shown in FIG. 13, the process may refer to the process in FIGS. 14A to 14G. As shown in FIG. 14A, the glass substrate 500 can be received as a carrier for supporting the semiconductor package structure during the manufacturing process. In some embodiments, the releasing layer 501 may be applied to the upper surface of the glass substrate 500. In some embodiments, when the bonded SoC structure 201 and the memory structure 202 is placed on the releasing layer 501, the memory structure 202 is positioned in proximity to the releasing layer 501, and therefore the bump pad structures 506 are formed on the SoC structure 201.

The following packaging process, including encapsulating operations, forming redistribution structures, bump plating operation, and de-bonding operation illustrated in FIGS. 14B to 14G, is substantially identical to the process previously described in FIGS. 12B to 12G. Therefore, the descriptions are omitted here for brevity.

According to the embodiments of the present disclosure, in packaging the SoC structure, the memory structure, and the electrical components including silicon bridge die, semiconductor capacitor structure, and voltage converter, the positions of these structures and components can be differ from different embodiments. Even though there are many variations in the selection of components and the placement of them, the present disclosure is aimed at revealing several feasible, easy-to-package, and effective structures, and providing corresponding packaging methods to meet the diverse application scenarios, especially for the technological development of computing units, providing low-cost and high-performance semiconductor packaging structures.

In one exemplary aspect, a semiconductor package structure is provided. The semiconductor package structure includes a first redistribution structure, a SoC structure, a memory structure, a first electronic component, and a first encapsulation layer. The first redistribution structure has a first side and a second side opposite to the first side. The SoC structure is on the first side of the first redistribution structure. The memory structure is adjacent to the SoC structure and on the first side of the first redistribution structure. The first electronic component is on the second side of the first redistribution structure and electrically connected to at least one of the SoC structure or the memory structure. The first encapsulation layer encapsulates the first electronic component. The first electronic component includes a semiconductor capacitor structure or a voltage converter.

In another exemplary aspect, a semiconductor package structure is provided. The semiconductor package structure includes a redistribution structure, a SoC structure, a memory structure, a first electronic component, and a second encapsulation layer. The redistribution structure has a first side and a second side opposite to the first side. The SoC structure is on the first side of the redistribution structure. The memory structure is adjacent to the SoC structure and on the first side of the redistribution structure. The first electronic component is on the first side of the redistribution structure and electrically connected to at least one of the SoC structure or the memory structure. The second encapsulation layer encapsulates the first electronic component, the SoC structure, and the memory structure. The first electronic component includes a first semiconductor capacitor structure or a voltage converter.

In yet another exemplary aspect, a semiconductor package structure is provided. The semiconductor package structure includes a first redistribution structure, a SoC structure, a memory structure, and a first electronic component. The first redistribution structure has a first side and a second side opposite to the first side. The SoC structure is on the first side of the first redistribution structure. The memory structure is adjacent to the SoC structure and on the first side of the first redistribution structure. The first electronic component is on the second side of the first redistribution structure and electrically connected to the memory structure. The first electronic component includes an active device.

The foregoing outlines structures of several embodiments so that those skilled in the art may better understand the aspects of the present disclosure. Those skilled in the art should appreciate that they may readily use the present disclosure as a basis for designing or modifying other operations and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package structure, comprising:
a first redistribution structure, having a first side and a second side opposite to the first side;
a SoC structure on the first side of the first redistribution structure;
a memory structure adjacent to the SoC structure and on the first side of the first redistribution structure;
a first electronic component on the second side of the first redistribution structure and electrically connected to at least one of the SoC structure or the memory structure; and
a first encapsulation layer encapsulating the first electronic component,
wherein the first electronic component comprises a semiconductor capacitor structure or a voltage converter.

2. The semiconductor package structure of claim 1, further comprising a second electronic component on the second side of the first redistribution structure, wherein the second electronic component comprises a bridge die electrically connecting the SoC structure and the memory structure.

3. The semiconductor package structure of claim 2, further comprising a second redistribution structure electrically coupled to the first electronic component and the second electronic component, wherein the second redistribution structure is disposed on a side of the first electronic component facing away from the first redistribution structure.

4. The semiconductor package structure of claim 3, wherein at least one of the first electronic component or the second electronic component comprises a plurality of through silicon vias (TSVs) electrically connecting the first redistribution structure and the second redistribution structure.

5. The semiconductor package structure of claim 4, wherein the first encapsulation layer comprises molding underfill (MUF).

6. The semiconductor package structure of claim 2, wherein the first encapsulation layer laterally spaces the first electronic component and the second electronic component apart.

7. The semiconductor package structure of claim 1, wherein a thickness of the first electronic component and a thickness of the second electronic component are substantially identical.

8. The semiconductor package structure of claim 1, further comprising a third electronic component on the first side of the first redistribution structure and electrically connected to at least one of the SoC structure or the memory structure, wherein the third electronic component comprises a semiconductor capacitor structure or a voltage converter.

9. The semiconductor package structure of claim 1, wherein the SoC structure is vertically stacked to the memory structure.

10. A semiconductor package structure, comprising:
a redistribution structure, having a first side and a second side opposite to the first side;
a SoC structure on the first side of the redistribution structure;
a memory structure adjacent to the SoC structure and on the first side of the redistribution structure;
a first electronic component on the first side of the redistribution structure and electrically connected to at least one of the SoC structure or the memory structure; and
a second encapsulation layer encapsulating the first electronic component, the SoC structure, and the memory structure,
wherein the first electronic component comprises a first semiconductor capacitor structure or a voltage converter.

11. The semiconductor package structure of claim 10, further comprising a second electronic component at the second side of the redistribution structure and under a projective coverage of the SoC structure and the memory structure.

12. The semiconductor package structure of claim 11, further comprising:
a first encapsulation layer encapsulating the second electronic component; and
a plurality of through vias in the first encapsulation layer, wherein the second electronic component are laterally surrounded by the plurality of through vias in the first encapsulation layer.

13. The semiconductor package structure of claim 10, wherein the voltage converter comprises an active device.

14. The semiconductor package structure of claim 10, wherein the voltage converter comprises a power management unit and a second semiconductor capacitor structure.

15. A semiconductor package structure, comprising:
a first redistribution structure, having a first side and a second side opposite to the first side;
a SoC structure on the first side of the first redistribution structure;
a memory structure adjacent to the SoC structure and on the first side of the first redistribution structure; and
a first electronic component on the second side of the first redistribution structure and electrically connected to the memory structure,
wherein the first electronic component comprises an active device.

16. The semiconductor package structure of claim 15, wherein the first electronic component comprises a power management unit and a semiconductor capacitor structure integrated with the power management unit.

17. The semiconductor package structure of claim 15, wherein the first electronic component comprises a power management die and a silicon capacitor die electrically connected to the power management die through a hybrid bonding layer.

18. The semiconductor package structure of claim 15, wherein the first electronic component comprises a power management die and a silicon capacitor die stacked with the power management die, a through silicon via positioned at least in one of the power management die or the silicon capacitor die.

19. The semiconductor package structure of claim 18, further comprising a second redistribution structure supporting the first electronic component and electrically connected to the first redistribution structure by the through silicon via.

20. The semiconductor package structure of claim 15, further comprising:
a second electronic component on the second side of the first redistribution structure, the second electronic component comprising a fully integrated voltage regulator (FIVR), a silicon capacitor die, or a bridge die; and
a third electronic component on the first side of the first redistribution structure, the third electronic component comprising a fully integrated voltage regulator (FIVR) or a silicon capacitor die.
